(19) United States
(12) Patent Application Publication
(10) Pub. No.: US 2006/0188743 A1
(43) Pub. Date: Aug. 24, 2006

(54) Fept magnetic thin film having perpendicular magnetic anisotropy and method for preparation thereof

(76) Inventors: Takeshi Seki, Miyagi (JP); Toshiyuki Shima, Miyagi (JP); Koki Takanashi, Miyagi (JP); Kazuhiro Hono, Ibaraki (JP)

Correspondence Address: WENDEROTH, LIND & PONACK, L.L.P., 2033 K STREET N. W., SUITE 800, WASHINGTON, DC, 20006-1021, US

(21) Appl. No.: 10/550,725

(22) PCT Filed: Mar. 25, 2004
(86) PCT No.: PCT/JP04/04152

§ 371 Date: Dec. 15, 2005

(30) Foreign Application Priority Data
Mar. 27, 2003 (JP) 2003-87789
Sep. 4, 2003 (JP) 2003-313158

(51) Int. Cl. B32B 15/01; C23C 14/00

(52) U.S. Cl. 428/669; 204/192.2; 428/681; 428/692.1

(57) ABSTRACT

An FePt magnetic thin film, characterized in that it has an atomic composition represented by the following formula:
FexPt100-x wherein 19<x<52; and a method for manufacturing the FePt magnetic thin film. The FePt magnetic thin film is novel, can be formed at a lowered temperature, and further, has perpendicular magnetic anisotropy.

### TECHNICAL FIELD

The present invention relate to an FePt magnetic thin film having perpendicular magnetic anisotropy and a method for manufacturing the same.

### BACKGROUND ART

In the recent advancement of highly information-oriented society, there is an urgent need for ultrahigh-density magnetic recording media that process and store a vast amount of information. Desirably, the magnetic-recording media have a magnetically isolated fine particle structure and the fine particles therein overcome thermal disturbance and are oriented in one direction. In particular for increase in the density of the magnetic recording media, it is necessary to reduce the size of ferromagnetic particles. However, when the size of ferromagnetic fine particles is reduced, the magnetic recording becomes unstable at room temperature because there is a criticality particle diameter below which the thermal disturbance becomes predominant. From this viewpoint, L1₀-structured ordered FePt alloys, which have great uniaxial crystalline magnetic anisotropy (Ku: 7.0×10⁷ erg/cc) and retain their ferromagnetism as superfine nanometer-sized particles, are attracting attention as materials for next-generation ultrahigh-density magnetic recording media.

The ordered FePt alloys also have an application as magnet because of their high uniaxial magnetic anisotropy. FePt alloys are superior in corrosion and oxidation resistances, compared to rare-earth magnets such as Nd- and Sm-based magnets. Some elements are added to the rare earth magnets for improvement in resistance to corrosion or oxidation, but the elements thus added deteriorate the magnetic properties. However, there is no need for addition of other elements to FePt alloys and the magnetic properties of FePt per se are reflected in the characteristics of magnet, and thus, use of FePt alloys is extremely advantageous. If realized, such thin film magnets superior in corrosion resistance, would be applied to ultra-small electromagnetic parts, ultra-small magnets for micromachines, dental attachments, medical therapy applying magnetic field locally, for example, to nerves, pumps for drug delivery systems delivering a trace amount of chemicals into the body, and the like.

However, the L1₀ structure is thermodynamically stable at room temperature, but FePt thin films prepared by sputtering cannot be converted (oriented) into an ordered structure because they are not exposed to the order-disorder transformation temperature present in a high temperature range during the manufacturing process. For the reason, it is necessary to use a high-temperature process, for example a process of forming a film on a heated substrate or heat-treating an ordered alloy thin film once formed, normally at a temperature of higher than 500° C. for obtaining an L1₀ ordered structure. However, materials currently used for hard disk devices do not have the resistance at a high temperature, and such a high-temperature process represents a great difficulty, from the practical point of view.

Although there are many manufacturing methods proposed recently aimed at decreasing the processing temperature, these low-temperature manufacturing methods often result in problems such as deterioration in magnetic properties, difficulty in controlling crystal orientation, and complication of manufacturing process due to addition of third element. Fe₅₀Pt₅₀ in the stoichiometric composition and the alloys in the Fe-rich composition were used in many of these manufacturing methods (Non-Patent document 1).

Recently, Takahashi et al. have succeeded in preparing a thin FePt film having the L1₀ structure at a low temperature by forming the film by sputtering on a substrate heated to 300° C. (Non-Patent document 2 and Patent document 1), but the film prepared at a low temperature was found to be dependent on film thickness in the subsequent studies and the ordering proceeded only when the film thickness is 100 nm or more.

Non-Patent document 1: M. Watanabe, M. Homma and T. Masumoto, Trans. J. Magn. Magn. Mater. 177, 1231 (1998)

Non-Patent document 2: T. K. Takahashi, M. Ohnuma, and K. Hono, Jpn. J. Appl. Phys. 40, L367 (2001)

Patent document 1: Japanese Patent Application Laid-Open No. 203-99920

### DISCLOSURE OF INVENTION

Accordingly, it is an object of this invention to provide a new FePt magnetic thin film that overcomes the problems of the traditional methods described above, can be formed at a lower temperature and has perpendicular magnetic anisotropy, and a method for manufacturing the same.

To solve the problems above, this invention provides firstly an FePt magnetic thin film characterized by having an atomic composition represented by the following formula:
FeₓPt₁₀₀₋ₓ

(19<x<52).

Secondly, this invention provides the Fe magnetic thin film characterized by having a film thickness of less than 100 nm and an L1₀ structure.

Thirdly, the FePt magnetic thin film characterized by being formed on a single crystalline substrate or an oxide undercoat layer on the surface thereof; fourthly, the FePt magnetic thin film formed via a thin layer of one or more of transition and noble metals formed as the undercoat layer; fifthly, the FePt magnetic thin film wherein the thin layer is a single layer or multiple layers; and sixthly, the FePt magnetic thin film wherein the thin film has a layer of one or more metals of Fe, Ag, Ni, Co and Cr and a layer of one or more metals of Au, Pt, and Cu, are provided

This invention additionally provides seventhly, a method for manufacturing any one of the FePt magnetic thin films above, characterized by forming the FePt magnetic thin film by sputtering on a single crystalline substrate, a substrate having an oxide undercoat layer formed thereon, or a substrate having a thin film of one or more of transition and noble metals as undercoat layer at a temperature in the range of 240° C. to 500° C., and eighthly, the method for manufacturing the FePt magnetic thin film wherein the FePt magnetic thin film is formed by sputtering at a temperature of 300° C. or lower.

This invention described above is completed based on the new findings obtained by various studies conducted by the inventors. That is, it is possible to prepare an ordered FePt-alloy thin film oriented in the direction perpendicular to the film and higher in crystalline magnetic anisotropy at a low temperature, by shifting the composition from the stoichiometric composition of Fe₅₀Pt₅₀ (at. %) to the Pt-rich side during preparation of the thin FePt film by sputtering.

In other words, this invention, which is developed based on the dependence of FePt orientation on composition at a low temperature, allows formation of thin FePt films in a wide range of compositions that are independent of film thickness and have the L1₀ structure even at a thickness of 10 nm or less, by sputtering at a practically feasible substrate temperature. In addition, an L1₀-structured FePt thin film having uniaxial magnetic anisotropy in the direction perpendicular to the film is formed successfully by epitaxial growth thereof on the substrate. The manufacturing method according to this invention differs significantly from conventional low-temperature manufacturing methods, in that it is possible to form an orientation-controlled L1₀structured ordered FePt-alloy thin film at a low temperature only by a simple method of changing the composition of the FePt phase. Further, the simple method allows generation of significantly higher crystalline magnetic anisotropy.

### BRIEF DESCRIPTION OF THE DRAWINGS

FIG. 1 is a chart showing X-ray diffraction patterns of FePt thin films prepared in Example 1.

FIG. 2 is a chart showing magnetization curves obtained in Example 2.

FIG. 3 is a chart showing a dependence of a spacing of lattice planes in a- and c-axial directions, the c/a (axial ratio), degree of order S, and crystalline magnetic anisotropy constant Ku of FePt thin film obtained to Example 3 on its composition.

FIG. 4 a chart showing X-ray diffraction patterns of Fe₃₈Pt₆₂ thin film obtained in Example 4.

FIG. 5 is a chart showing magnetization curves of FePt thin films obtained in Example 5.

FIG. 6 is a chart showing X-ray diffraction patterns of Fe₃₈Pt₆₂ thin film obtained in Example 6.

FIG. 7 is a chart showing magnetization curves of Fe₃₈Pt₆₂ thin film obtained in Example 7.

FIG. 8 is a chart showing X-ray diffraction patterns of Fe₃₈Pt₆₂ thin film obtained in Example 8.

FIG. 9 is a chart showing X-ray diffraction patterns of thin films obtained in Example 9.

FIG. 10 is charts showing magnetization curves of thin films obtained in Example 9.

FIG. 11 is a chart showing a relationship between Ku and a lattice mismatching of thin film obtained in Example 10.

FIG. 12 is a chart showing a dependence of magnetization on temperature in Example 11.

FIG. 13 is a chart showing a relationship between Fe concentration and Curie temperature Tc In Example 11.

### BEST MODE FOR CARRYING OUT THE INVENTION

This invention is characterized by the description above, and hereinafter, the embodiments thereof will be described

Firstly, the FePt magnetic thin film according to this invention should have a compositional region showing high uniaxial magnetic anisotropy. Thus, the FePt phase should have an alloy composition (atomic ratio) of FeₓPt₁₀₀₋ₓ, where 19<x<52.

In addition, the film thickness is preferably as thin as possible, considering industrial application, for example, to ultra-small electronic parts. Different from conventional methods, it is possible to form a thin film having the L1₀ structure having a thickness of not as thick as 100 mm, specifically in the range of 2 to 100 nm, by this invention.

It is necessary to control crystallization direction for providing an FePt thin film formed on a substrate with magnetic anisotropy, and it can be accomplished easily by selecting a single crystalline substrate properly. In order to control perpendicular orientation of an easy axis of magnetization, favorable are single crystalline substrates of MgO (001), NaCl (001), GaAs (001), and the like. Even when a non-single crystalline substrate such as glass plate is used, it becomes easier to control orientation by constructing an undercoat layer of an oxide such as MgO or ZnO on the surface of the substrate.

In this invention, it is quite important to select a favorable substrate and a favorable undercoat layer, for example of oxide or other substance, formed on the surface thereof in forming the FePt thin film.

In selecting the substrate and the undercoat layer for a FePt phase for the purpose of obtaining an ordered phase, important are the viewpoints of control and acceleration of the orientation of FePt phase. From the viewpoints above, it is also possible to form an FePt magnetic thin film via a thin layer of one or more of transition and noble metals as the undercoat layer on a substrate (favorably, single crystalline substrate or substrate having an oxide undercoat layer) in this invention.

In such a case, the thin layer may be a single layer or multiple layers, but in a more favorable embodiment, the thin layer preferably has a layer of one or more metals of Fe, Ag, Ni, Co and Cr (which may be called a seed layer) and a layer of one or more metals of Au, Pt, and Cu (which may be called a buffer layer). The seed layer preferably has a thickness of 0.2 to 2 nm, while the buffer layer a thickness of 5 to 50 nm.

In selecting the undercoat layer of the transition and noble metals, considered is a fact that it is possible to obtain a higher degree of ordering and a larger perpendicular magnetic anisotropy in the Pt-rich composition region, by selecting an undercoat layer larger in lattice mismatching with the FePt layer. It is also possible to control the anisotropy by the undercoat layer selected.

It is of course not always necessary to form the undercoat layer described above. By deciding the composition and the film-forming condition from the viewpoint of FePt phase ordering, it is possible to control the orientation of the FePt thin film. For example, as shown in the Examples below, it is possible to control the orientation of the FePt layer on a single crystalline MgO (001) substrate even without use of an undercoat layer such as the seed or buffer layer, and the ordering proceeds in the Pt-rich composition region at a temperature in the range of 240° C. to 500° C. For orientational control at the time, it would be favorable, for example, to form a film by sputtering under an Ar (argon) gas pressure in the range of 3 to 40 mTorr.

The FePt magnetic thin film according to this invention is prepared by sputtering at a temperature lower than that traditionally used, however, a substrate temperature higher to some extent is needed during FePt film deposition, for obtaining an ordered phase and a larger uniaxial magnetic anisotropy. On the other hand, the processing temperature is desirably lower, from the practical viewpoint. For that purpose, the film should be formed at a substrate temperature in the range of 240° C. to 500° C., and the most important feature of this invention is that it is possible to form a film at a lower temperature of 300° C. or lower.

When a material having a high coercive force is used as a recording medium, a high magnetic field is needed for writing information (magnetization curling). Thus, a heat-assisted magnetic recording method was proposed. Magnetization (information) is partially disappeared by heating a recording medium locally, for example with a laser beam, and thus raising the temperature of the magnetic material dose to the Curie temperature. By applying a magnetic field from outside at the time, it becomes possible to magnetize the recording medium in the direction of the magnetic field after cooling. Considering the trend of such an information-recording method, it is important to control the Curie temperature, in application of the heat-assisted method to magnetic recording and others. It is where the advantageous effects of the FePt thin film according to this invention are used. That is, it is possible to form a thin film of ordered FePt alloy having a Curie temperature Tc lower than that of a bulk in the Pt-rich composition region at a low temperature. It is also possible to control the Tc arbitrarily by adjusting the composition.

Hereinafter, this invention will be described in more detail with reference to Examples, but it should be understood that this invention is not restricted by the following Examples.

### EXAMPLES

### Example 1

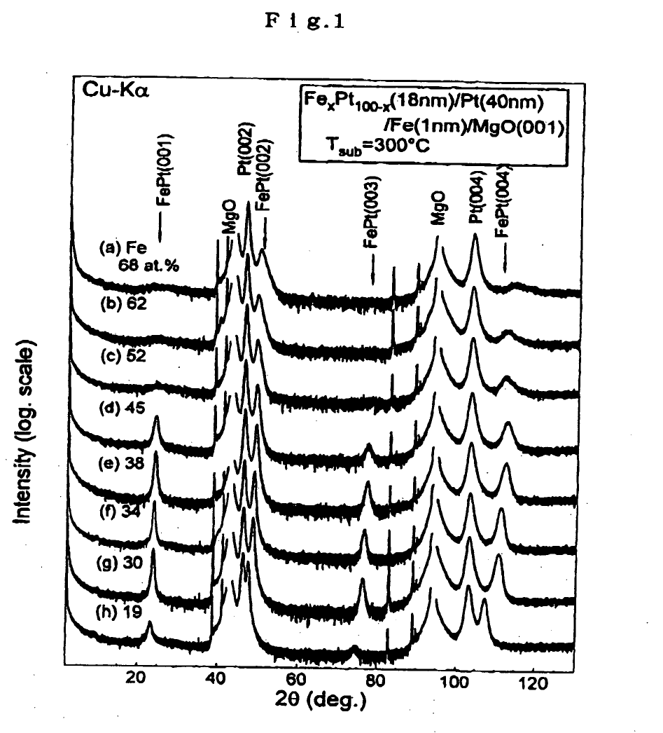

By using a UHV-compatible magnetron-sputtering apparatus having an ultimate vacuum of 1×10⁻⁹ Torr or less, Fe seed layer of 1 nm and Pt buffer layer of 40 nm in thickness were formed on a single crystaline MgO (001) substrate at room temperature under an Ar gas pressure of 1 mTorr, and then, FePt thin film of 18 nm in thickness was formed by sputtering at a substrate temperature of 300° C. under an Ar gas pressure of 5 mTorr. FIG. 1 shows X-ray diffraction patterns of the FePt thin films obtained. In the Formula FeₓPt₁₀₀₋ₓ, x's are respectively 68 (a), 62 (b), 52 (c), 45 (d), 38 (e), 34 (f), 30 (g), and 19 (h). Because only (00n) diffraction peaks were observable, and thus it is understood that the FePt layer is grown on the MgO (001) substrate In the directional relationship of MgO (001)//FePt (001). In all of the FePt thin films above in any composition, principal reflection peaks, (002) and (004) diffraction peaks, of the FePt phase and Pt (002) and (004) diffraction peaks of the buffer layer are observed. Superlattice-reflected lines, i.e., (001) and (003) diffraction peaks, of FePt were observed for the FePt thin films of x<45, indicating that ordered FePt alloys having the L1 structure were obtained. The integral intensity of the superlattice-reflected lines was highest in the FePt thin film of x=38, indicating that the highest ordering proceeded in this thin film. In the FePt thin film having a stoichiometric composition, there was no superlattice-reflected line observed, indicating that a substrate temperature of 300° C. is still lower for the ordering of the FePt thin film having a stoichiometric composition. However, it is understood that the ordering proceeds and it is possible to obtain the L1₀ ordered structure even at a substrate temperature of 300° C. by shifting the composition of the FePt thin film to the Pt-rich side. It became clear that the FePt ordering proceeded at a lower temperature In a composition region of 19<x<52.

### Example 2

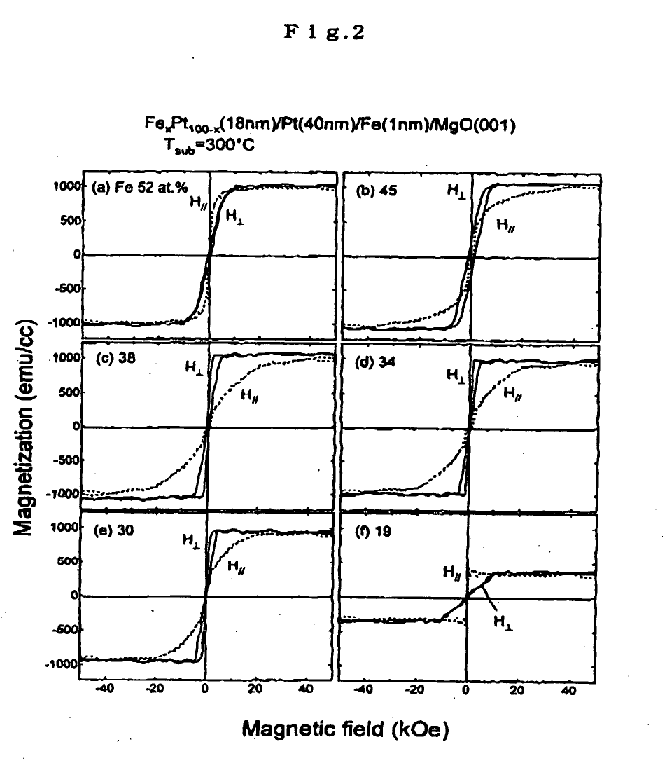

Fe seed layer of 1 nm and Pt buffer layer of 40 nm in thickness were formed on a single crystalline (001) substrate at room temperature in a similar manner to Example 1, and then, FePt layer of 18 nm in thickness was formed at a substrate temperature of 300° C. FIG. 2 shows the magnetization curves obtained when measured in the direction of the sample film and the direction perpendicular to the film. In the Formula FeₓPt₁₀₀₋ₓ, x's are respectively 52 (a), 45 (b), 38 (c), 34 (d), 30 (e), and 19 (f). In the FePt thin film of x=52, the direction of film(surface) represents the easy axis of magnetization, however, apparently, the easy axis of magnetization is shifting into the direction perpendicular to the film gradually, as x is reduced. The crystalline magnetic anisotropy constant Ku of the FePt thin film of x=38, as calculated from the area enclosed by the magnetization curves in the direction of the film and the direction perpendicular to the film, was a very large value of 1.8×10⁷ erg/cc. It is obvious that it is possible to form a FePt thin film having a uniaxial magnetic anisotropy in the diction perpendicular to the film in a composition range of 19<x<52.

### Example 3

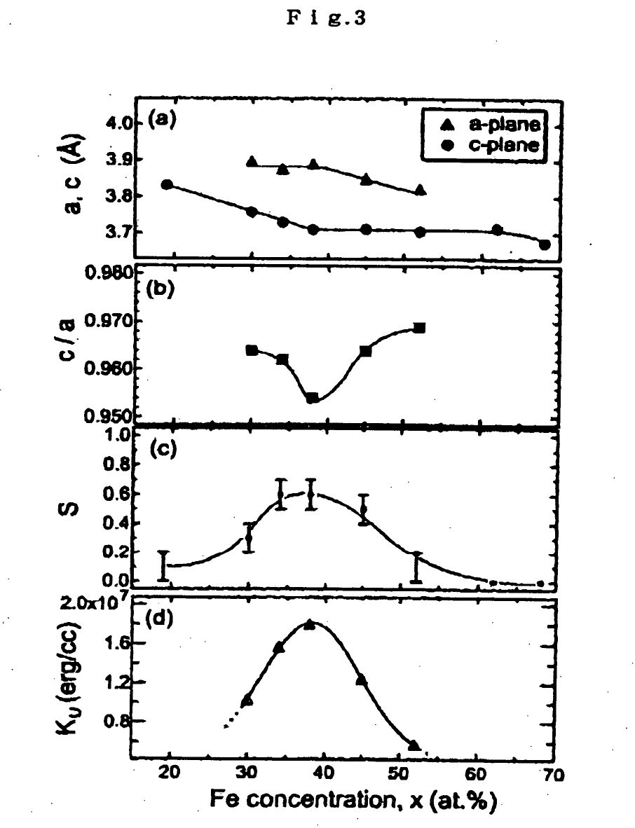

Fe seed layer of 1 mm and Pt buffer layer of 40 nm in thickness were formed on a single crystalline MgO (001) substrate at room temperature in a similar manner to Example 1, and then, FePt film of 18 nm in thickness was formed at a substrate temperature of 300° C.; and FIG. 3 shows the dependence of the spacing of the lattice planes in the a- and c-axial directions, the axial ratio c/a of c- and a-axes, the degree of ordering S, and the crystalline magnetic anisotropy constant Ku of the FeₓPt₁₀₀₋ₓ phase on the composition. The spacing of c lattice planes consistently decreased as x is increased up to 38, and then remained constant in the range of 38≦x≦68. On the other hand, the spacing of a lattice planes remained constant in the range of 38≦x and decreased in the range of x≧38. It is possible to estimate the degree of distortion in crystal lattice from the ratio c/a. Apparently, the c/a value reached the minimum of 0.955 at x=38, and both S and Ku were also the maximum values at the time.

### Example 4

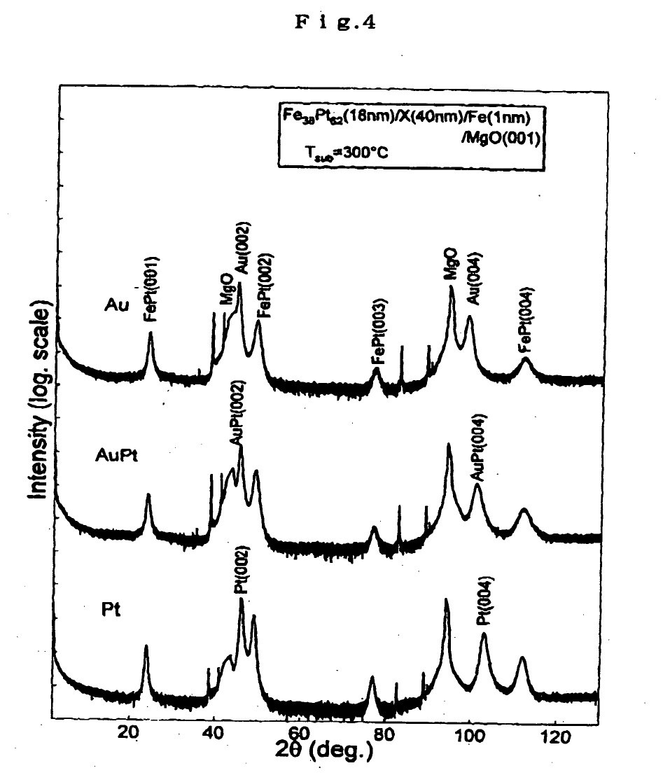

Fe seed layer of 1 nm and several metal-alloy buffer layers of 40 nm in thickness were formed on a single crystalline MgO (001) substrate in a similar manner to Example 1 at room temperature and then, FePt film of 18 nm in thickness was formed at a substrate temperature of 300° C.; and FIG. 4 shows the X-ray diffraction pattern of the Fe₃₈Pt₆₂ thin films formed. The buffer layers selected were those of Au, AuPt, and Pt. There were no diffraction lines form other planes when any buffer layer was used, and accordingly, and the superlattice-reflected lines, (001) and (003) diffraction peaks, of the FePt phase were observed distinctively. The results above definitely reveals that it is possible to form an ordered FePt-alloy thin film having the L1₀ structure at a low temperature by selecting a buffer layer lower in the lattice mismatching with FePt.

### Example 5

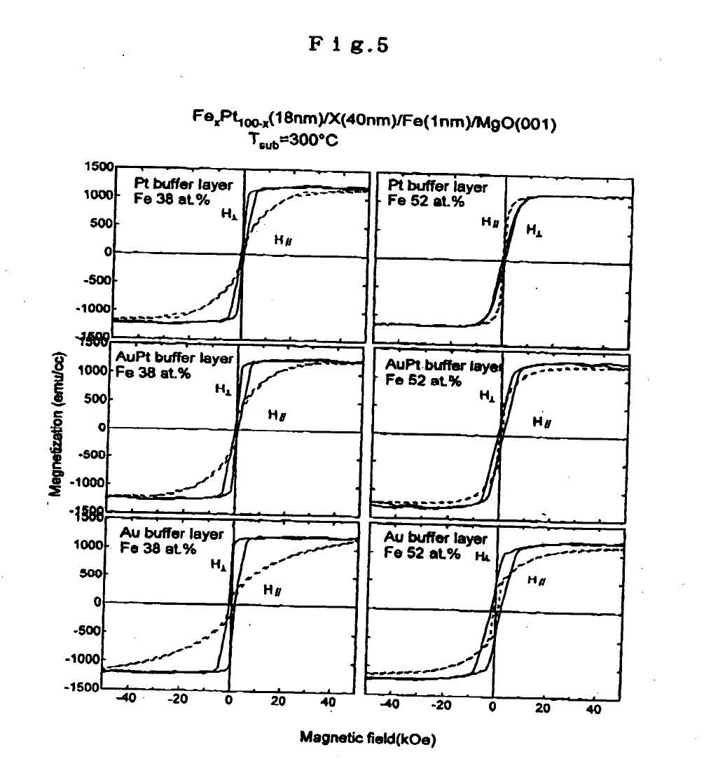

Fe seed layer of 1 nm and a buffer layer of 40 nm in thickness were formed on a single crystalline MgO (001) substrate at room temperature in a ar manner to Example 1, and then, FePt thin film of 18 mm in thickness was formed at a substrate temperature of 300° C.; and FIG. 5 shows the magnetization curves of the FePt thin film formed. The buffer layers selected was those of Au, AuPt, and Pt. In the Formula FeₓPt₁₀₀₋ₓ, x=38 or 52. The easy axis of magnetization of the Fe₃₈Pt₆₂ thin film was in the direction perpendicular to film when any buffer layer was used, and the crystalline magnetic anisotropy constant calculated from the magnetization curve was apparently greater than that of the Fe₅₂Pt₄₈ thin film. When Au, which is greater in the lattice mismatching with FePt than Pt, is selected for the buffer layer, the FePt film apparently has a crystalline magnetic anisotropy greater than that when Pt buffer layer was used, under the influence of the distortion by the undercoat layer. The results indicate that it is possible to control anisotropy by properly selection of the buffer layer.

### Example 6

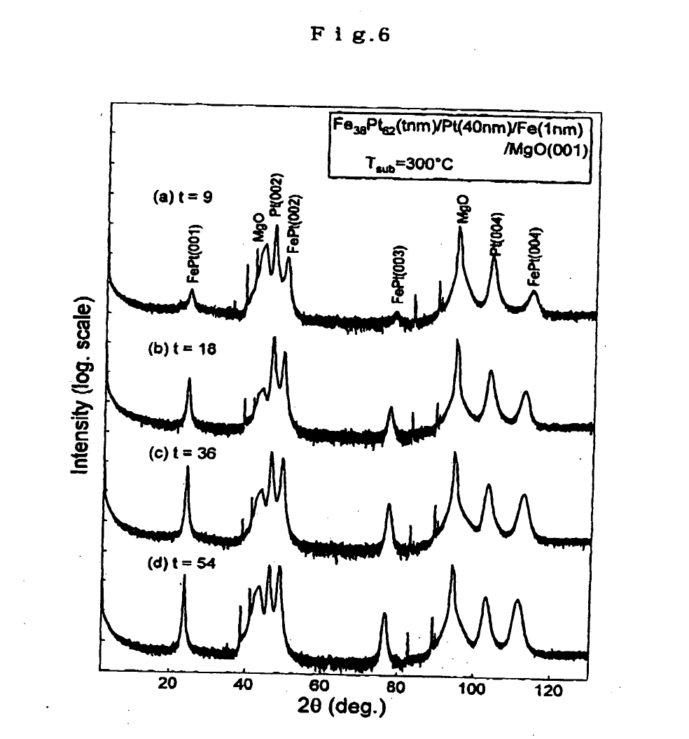

Fe seed layer of 1 nm and Pt buffer layer of 40 nm in thickness were formed on a MgO (001) single crystal substrate at room temperature in a similar manner to Example 1, and then, Fe thin films having varying thickness t were formed at a substrate temperature of 300° C.; and FIG. 6 shows the X-ray diffraction patterns thereof. The film thickness t of the FePt layer was altered from 9 nm to 54 nm. The superlattice-reflected lines from the FePt phase, (001) and (003) diffraction peaks, are observed at any film thickness, indicating generation of an ordered FePt-alloy thin film having the L1₀ structure. In addition, increase in the intensity of the peak derived from the L1₀ ordered structure associated with increase in film thickness indicates formation of FePt thin film having a higher degeree of order.

### Example 7

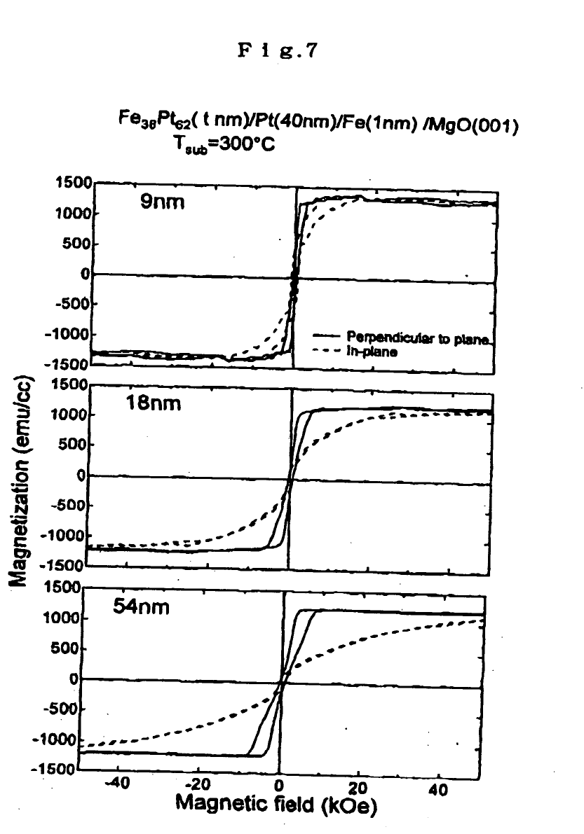

Fe seed layer of 1 nm and Pt buffer layer of 40 nm in thickness were formed on a single crystalline MgO (001) substrate at room temperature in a similar manner to Example 1 and then, Fe₃₈Pt₆₂ thin films were prepared at a substrate temperature of 300° C. while the film thickness t is altered; and FIG. 7 shows the magnetization curves of these thin films. The thickness t of the FePt film was altered from 9 to 54 nm. The easy of magnetization of the FePt Mm was in the direction perpendicular to film at any one of the film thicknesses, indicating that the film has uniaxial magnetic anisotropy. In addition, the deterioration in the saturation of magnetization in the direction of the hard axis of magnetization (in this case, direction of the film) associated with increase in film thickness indicates that the thin film has an increased crystalline magnetic anisotropy.

### Example 8

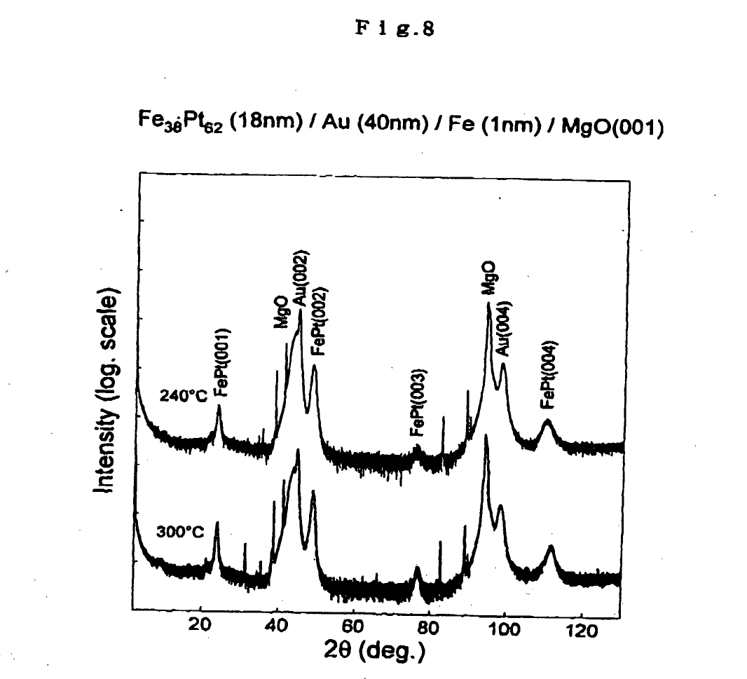

Fe seed layer of 1 nm and Au buffer layer of 40 nm in thickness were formed on a single crystalline MgO (001) substrate at room temperature in a similar manner to Example 1 and then, Fe₃₈Pt₆₂ thin films of 18 nm in thickness were formed at substrate temperatures of 240° C. and 300° C.; and FIG. 8 shows the X-ray diffraction patterns of these films. The superlattice-reflected lines of the Fe₃₈Pt₆₂ phase, (001) and (003) diffraction peaks, can be observed in the X-ray diffraction pattern of the Fe₃₈Pt₆₂ thin film prepared at a substrate temperature of 240° C. The fact demonstrates that the ordering proceeds during film forming under the condition of a substrate temperature of 240° C. or more.

### Example 9

FePt thin film of 18 mm in thickness were formed on a single crystalline MgO (001) substrate directly by UHV magnetron sputtering under the conditions of an Ar gas pressure of 5 mTorr and a temperature of 300° C.

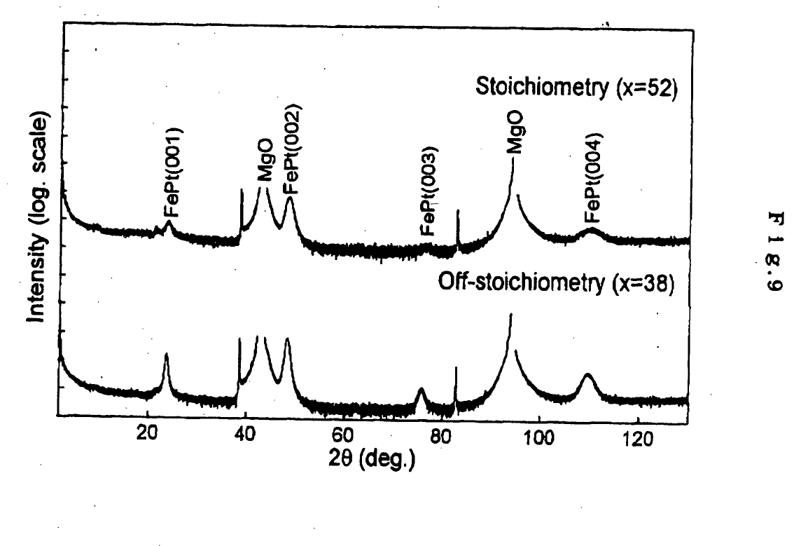

FIG. 9 shows the X-ray diffraction patterns of these thin films. The films are FeₓPt₁₀₀₋ₓ thin films, wherein x=52 (stoichiometric composition) and x=38 (off-stoichiometric composition).

Only FePt (00n) diffraction peaks were observable in the results obtained from the FePt thin films formed on the MgO (001) substrate, which indicates that the sample thin film is (001) oriented. Distinct FePt (001) and (003) superlattice-reflected lines were not observed from the Fe₅₂Pt₄₈ thin film that has an almost stoichiometric composition, indicating that no ordering proceeded. However, the Fe₃₈Pt₆₂ thin film in the Pt-rich side composition region showed distinct superlattice-reflection lines, demonstrating that the L1₀ ordered structure was formed.

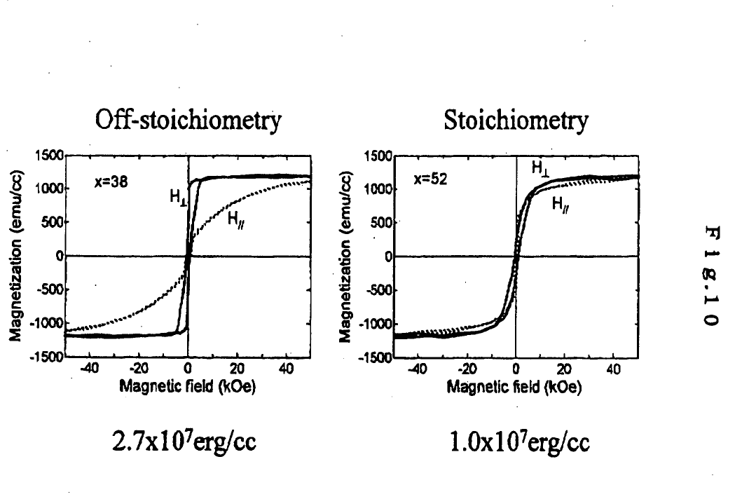

FIG. 10 is a chart wherein the solid line indicates the magnetization curve as determined in the direction perpendicular to the film and the dashed line as determined in the direction of film. The Fe₅₂Pt₄₈ thin film does not have perpendicular magnetic anisotropy in the direction perpendicular to the film, while the Fe₃₈Pt₆₂ thin film having a Pt-rich side composition has a high perpendicular magnetic anisotropy of Ku=2.7×10⁷ erg/cc.

The results above indicate that for example the orientation proceeds even without use of a seed layer and a buffer layer in the Pt-rich composition region of FeₓPt₁₀₀₋ₓ (in at. %) 19<x<52 and in a temperature range of 240 to 500° C. by controlling the ordering of the FePt layer on MgO (001) single crystal substrate. It was also confirmed that it is preferable to control the Ar gas pressure in 3 to 40 mTorr during film deposition for the orientational control at the time.

### Example 10

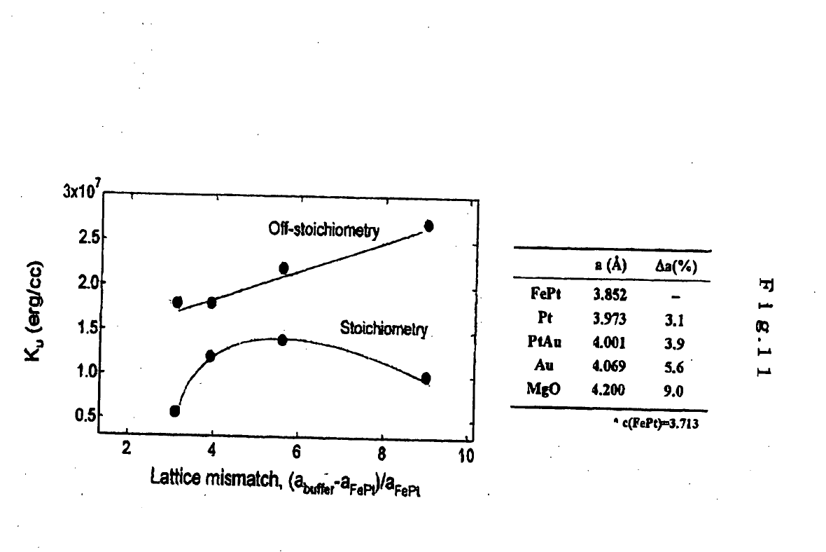

FePt thin films having various undercoat layers were prepared in a similar manner to Example 1. Influences of lattice mismatching on these thin films were analyzed. The results shown in FIG. 11 indicate that it is possible to obtain a larger uniaxial magnetic anisotropic energy by using an undercoat layer larger in lattice mismatching for the Fe₃₈Pt₆₂ thin film having a composition in the Pt-rich side composition region, while there is the lattice mismatching with undercoat layer best for obtaining perpendicular magnetic anisotropy for the Fe₅₂Pt₄₈ thin film having an almost stoichiometric composition.

### Example 11

Fe seed layer (1 mm) and Pt buffer layer (40 nm) and FePt thin film (18 mm) were formed on a MgO (001) substrate by UHV-magnetron sputtering under the conditions of an Ar gas pressure of 5 mTorr and a temperature of 300° C. The following six kinds of compositions were used then, and the dependence of magnetization on temperature in each case was determined.

FeₓPt₁₀₀₋ₓ: x=30, 34, 38, 45, 52, and 62.

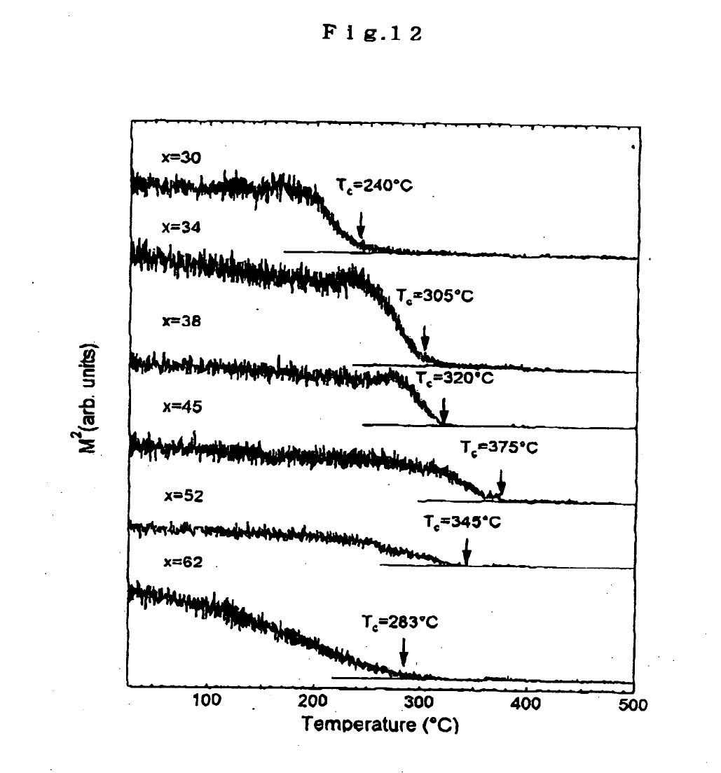

FIG. 12 shows the dependence of the magnetization on the temperature of each of the FePt thin films prepared by using Pt buffer layer at a low temperature. Fe₃₈Pt₆₂ thin film, which had higher degree of order and uniaxial magnetic anisotropy, had Tc of 320° C. The Tc is lower than the Tc 480° C. reported for the bulk sample in stoichiometric composition (Phys. Z., 36 (1935) 544). The result indicates that it is possible to prepare an ordered FePt-alloy thin film higher in the degree of order and magnetic anisotropy and having a Curie temperature lower than the bulk value, at a low temperature in the Pt-rich side composition region.

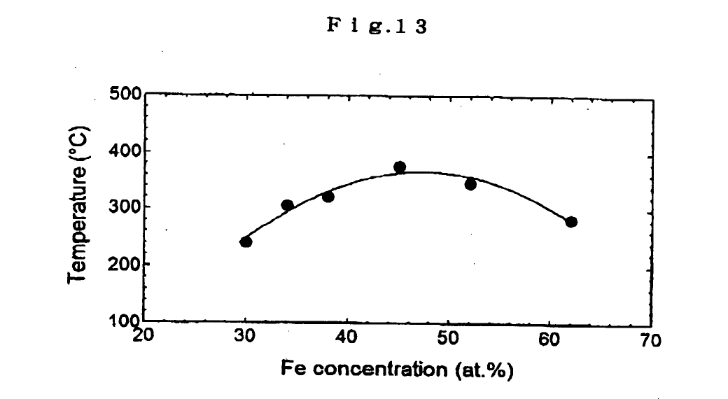

FIG. 13 shows the change in Curie temperature Tc, dependent on Fe concentration x (at. %) of the FePt thin films prepared at a low temperature by using the Pt buffer layer. The X-ray diffraction pattern shows that the sample of x=62 presumably having a disordered structure has a Tc value identical with the literature value of the disordered phase (ASM International, USA, (1995), p. 371). The sample of x=52 in the almost stoichiometric composition has a Tc value between the Tc values of ordered and disordered phase, indicating that the ordering is insufficient. The sample of x=38 has a value almost identical with the literature value for ordered phase.

### INDUSTRIAL APPLICABILITY

As described above in detail, this invention provides a FePt thin film having a greater uniaxial magnetic anisotropy that is prepared in a simpler process at a lower temperature. It provides a technology significantly more advantageous than that traditionally practiced, concerning the thin film used as a magnetic recording medium.

Hard disk drive is particularly important among many information storage devices and there is an established market demanding large-capacity magnetic recording media, and this invention is extremely valuable in this market.

1-8. (canceled)

9. An FePt magnetic thin film having an atomic composition represented by the following Formula:
FeₓPt₁₀₀₋ₓ
(19<x≦52).

10. The FePt magnetic thin film according to claim 9, having a thickness of less than 100 nm and an L1₀ structure.

11. The FePt magnetic thin film according to claim 9, being formed on a single crystalline substrate or on an oxide undercoat layer formed on the surface thereof.

12. The FePt magnetic thin film according to claim 11, being formed via a thin layer of one or more of transition and noble metals formed as an undercoat layer.

13. The FePt magnetic thin film according to claim 12, wherein the thin layer is a single layer or multiple layers.

14. The FePt magnetic thin film according to claim 13, wherein the thin layer has a layer of one or more of Fe, Ag, Ni, Co and Cr and a layer of one or more of Au, Pt, and Cu.

15. A method of producing the FePt magnetic thin film according to claim 9, characterized by forming the FePt magnetic thin film by sputtering on a single crystalline substrate, a substrate having an oxide undercoat layer formed thereon, or a substrate having a thin layer of one or more of transition and noble metals as undercoat layer at a temperature in the range of 240° C. to 500° C.

16. The method of producing the FePt magnetic thin film according to claim 15, wherein the FePt magnetic thin film is formed by sputtering at a temperature of 300° C. or lower.
